(19) United States
(12) Patent Application Publication
(10) Pub. No.: US 2006/0049519 A1
(43) Pub. Date: Mar. 9, 2006

(54) Semiconductor device and method for manufacturing semiconductor device

(75) Inventor: Tetsuya Otsuki, Fujimi-machi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/211,764

(22) Filed: Aug. 26, 2005

(30) Foreign Application Priority Data
Sep. 6, 2004 (JP) 2004-258739

(51) Int. Cl. H01L 23/48; H01L 23/52

(52) U.S. Cl. 257/737; 257/738; 257/686; 257/778

(57) ABSTRACT

A semiconductor device, comprises: a carrier substrate in which a semiconductor chip is mounted; and a land formed in the carrier substrate and arranged in a region different from the mounting face of the semiconductor chip, wherein a coarse face, the surface roughness of which is 20 through 100 μm, is formed in a bonding face of the land.

### BACKGROUND OF THE INVENTION

1. Technical Field

The present invention relates to semiconductor devices and a method for manufacturing semiconductor devices, which, in particular, are suitably applied to chip-size packages (CSP) or ball grid arrays (BGA).

2. Related Art

In the conventional semiconductor devices, in order to attain the miniaturization of semiconductor packages, there is a method using a chip-size package or a ball grid array. In such chip-size package or ball grid array, the semiconductor package can be configured using a carrier substrate in which a semiconductor chip is mounted. Here, when mounting, on a motherboard, a carrier substrate in which a semiconductor chip is mounted, the carrier substrate is bonded to the motherboard using a solder ball or a lead-free ball. Then, in order to bond the solder ball or lead-free ball to the carrier substrate and motherboard, the land is formed in the carrier substrate and motherboard.

Here, as the material of the land, copper is typically used. Then, in order to secure the temperature cycle resistance and ball shear strength, nickel and gold plating is applied on the base material of the land.

Moreover, in recent years, in response to the miniaturization, higher performance and more sophistication of cellular phones or the like, the semiconductor packages, such as the chip-size packages or ball grid arrays are beginning to be mounted in the cellular phones. For this reason, in order to improve the impact resistance at the time of dropping the product, the solder ball or lead-free ball is directly bonded onto a copper base without applying nickel and/or gold plating on the base material of the land. [0004]

Japanese Unexamined Patent Publication No. 10-340972 is an example of the related art. According to the art, in order to prevent cracks from occurring in the solder ball during the temperature cycle, a method for forming the edge of the opening of a solder resist layer in a tapered shape is disclosed.

However, if the solder ball or lead-free ball is directly bonded on the copper base, the impact resistance at the time of dropping the product will be improved, however, there are problems that the shearing strength (the lateral strength), temperature cycle resistance, and ball shear strength will deteriorate.

On the other hand, if nickel and/or gold plating is applied to the land, the shearing strength, temperature cycle resistance, and ball shear strength will be secured, however, since the strength of an alloy called (Cu, Ni)₆Sn₅ is weak in the peeling direction, there is a problem that the impact resistance at the time of dropping the product will deteriorate.

### SUMMARY

An advantage of the invention is to provide semiconductor devices and a method for manufacturing the semiconductor devices, capable of improving the impact resistance while suppressing the deterioration of shearing strength.

According to an aspect of the invention, a semiconductor device includes: a carrier substrate in which a semiconductor chip is mounted; and a land formed in the carrier substrate and arranged in a region different from the mounting face of the semiconductor chip, wherein a coarse face, the surface roughness of which is 20 through 100 μm, is formed in the bonding face of the land.

Accordingly, it is possible to cause a protruding electrode to bite into the land while enabling the bonding area to be increased, and thus the lateral move of the protruding electrode to be bonded to the land can be suppressed. For this reason, it is possible to secure the strength in the peeling direction while suppressing the deterioration of shearing strength, and thus the temperature cycle resistance and the ball shear strength can be secured, and the impact resistance can be improved.

According to another aspect of the invention, a semiconductor device includes: a carrier substrate in which a semiconductor chip is mounted; and a land formed in the carrier substrate and arranged in a region different from the mounting face of the semiconductor chip, wherein a recess is formed in the bounding face of the land.

Accordingly, it is possible to cause a protruding electrode to bite into the land while enabling the bonding area to be increased, and thus the strength in the peeling direction can be secured while suppressing the deterioration of shearing strength.

According to another aspect of the invention, a semiconductor device includes: a carrier substrate in which a semiconductor chip is mounted; and a land formed in the carrier substrate and arranged in a region different from the mounting face of the semiconductor chip, wherein a slit is formed in the bonding face of the land.

Accordingly, it is possible to cause a protruding electrode to bite into the land while enabling the bonding area to be increased, and thus the strength in the peeling direction can be secured while suppressing the deterioration of shearing strength.

According to another aspect of the invention, a semiconductor device includes: a carrier substrate in which a semiconductor chip is mounted; and a land formed in the carrier substrate and arranged in a region different from the mounting face of the semiconductor chip, wherein a cut is formed in the bonding face of the land.

Accordingly, it is possible to cause a protruding electrode to bite into the land while enabling the bonding area to be increased, and thus the strength in the peeling direction can be secured while suppressing the deterioration of shearing strength.

According to another aspect of the invention, a semiconductor device includes: a carrier substrate in which a semiconductor chip is mounted; a land formed in the carrier substrate and arranged in a region different from the mounting face of the semiconductor chip; and a plated layer formed in a part of the bonding face of the land.

Accordingly, after bonding a protruding electrode onto the base material of the land, it is possible to bond the protruding electrode also to the plated layer, and it is possible to cause the protruding electrode to bite into the plated layer. For this reason, it is possible to secure the strength in the peeling direction in the bonding portion in between the protruding electrode and the base material of the land, while the shearing strength in the bonding portion in between the protruding electrode and the plated layer can be secured, and thus the impact resistance can be improved while suppressing the deterioration of shearing strength.

It is preferable that the plated layer be a monolayer structure of Pd, a monolayer structure of Au, a monolayer structure of Sn, a multi-layered structure of Ni/Au, a multi-layered structure of Pd/Ni, or a multi-layered structure of Pd/Ni/Au.

Accordingly, the protruding electrode can be bonded stably to the plated layer, and the shearing strength can be secured in the bonding portion in between the protruding electrode and the plated layer.

It is preferable that the semiconductor device further includes: a protruding electrode bonded to the land; and a motherboard in which the carrier substrate is mounted via the protruding electrode.

Accordingly, it is possible to secure the shearing strength and the impact resistance while enabling the mounting area of the semiconductor package to be reduced, and thus the miniaturization, higher performance and more sophistication of portable apparatus, such as cellular phones can be attained.

It is preferable that the base material of the land is Cu, and the protruding electrode is a solder ball or a lead-free ball.

Accordingly, the solder ball or lead-free ball can be bonded directly on the copper base material, and thus it is possible to improve the impact resistance at the time of dropping the product.

Moreover, according to another aspect of the invention, a method for manufacturing a semiconductor device includes the steps of: forming a land on a carrier substrate, the land being arranged in a region different from the mounting face of the semiconductor chip; covering the periphery of the land with a solder resist; forming a coarse face, the surface roughness of which is 20 through 100 μm, in the surface of the land by carrying out a surface treatment or a surface processing of the land; and mounting the semiconductor chip on the carrier substrate.

Accordingly, while the coarse face can be formed on the surface of the land, thereby enabling the bonding area to be increased, it is possible to cause the protruding electrode to bite into the land. For this reason, the strength in the peeling direction can be secured and the deterioration of shearing strength can be suppressed.

According to another aspect of the invention, a method for manufacturing a semiconductor device includes the steps of forming a land on the carrier substrate, the land being arranged in a region different from the mounting face of the semiconductor chip and in the bonding face of which a penetrating slit or a cut is prepared; covering the periphery of the land with a solder resist; and mounting the semiconductor chip on the carrier substrate.

Accordingly, it is possible to form the penetrating slit or the cut in the land collectively at the time of forming the land, and it is possible to cause the protruding electrode to bite into the land. For this reason, the strength in the peeling direction can be secured without involving the increase of the process, and the deterioration of shearing strength can be suppressed.

According to another aspect of the invention, a method for manufacturing a semiconductor device includes the steps of forming a land on a carrier substrate, the land being arranged in a region different from the mounting face of a semiconductor chip; forming a slit or a recess on the bonding face of the land by carrying out a half etching of the land in the state that a part of the bonding face of the land is covered with resist; and mounting the semiconductor chip on the carrier substrate.

Accordingly, it is possible to cause the protruding electrode to bite into the land, while enabling the bonding area to be increased. For this reason, it is possible to suppress the deterioration of shearing strength, while attaining the miniaturization of the semiconductor package, and the impact resistance can be improved.

According to another aspect of the invention, a method for manufacturing a semiconductor device includes the steps of forming a land on a carrier substrate, the land being arranged in a region different from the mounting face of a semiconductor chip; forming a plated layer in the portion being exposed from the resist on the bonding face of the land by carrying out a plating treatment in the state that a part of the bonding face of the land is covered with resist; and mounting the semiconductor chip on the carrier substrate.

Accordingly, it is possible to form the plated layer selectively in a part of the bonding face of the land, and after bonding the protruding electrode on the base material of the land, the protruding electrode can be bonded also to the plated layer. For this reason, it is possible to suppress the deterioration of shearing strength, while attaining the miniaturization of the semiconductor package, and it is possible to improve the impact resistance.

It is also preferable that the method for manufacturing a semiconductor device further include the step of mounting, on a mother board, a carrier substrate in which the semiconductor chip is mounted via the protruding electrode bonded to the land.

Accordingly, it is possible to secure the shearing strength and the impact resistance while enabling the mounting area of the semiconductor package to be reduced, and thus the miniaturization, higher performance and more sophistication of portable apparatus, such as cellular phones can be attained.

### BRIEF DESCRIPTION OF THE DRAWINGS

The invention will be described with reference to the accompanying drawings, wherein like numbers refer to like elements, and wherein:

FIG. 1 is a sectional view showing a schematic configuration of a semiconductor device concerning a first embodiment of the invention;

FIG. 2 is a sectional view showing a method for manufacturing the semiconductor device of FIG. 1;

FIG. 3 is a sectional view showing a method for manufacturing a circuit substrate concerning a second embodiment of the invention;

FIG. 4 is a sectional view showing a method for manufacturing a circuit substrate concerning a fourth embodiment of the invention;

FIG. 5 is a sectional view showing a schematic configuration of a semiconductor device concerning a fifth embodiment of the invention;

FIG. 6 is a sectional view showing a method for manufacturing the semiconductor device of FIG. 5; and

FIG. 7 is a plane view showing configuration examples of the bonding face of a land concerning the embodiment of the invention.

### DESCRIPTION OF THE EMBODIMENTS

Hereinafter, semiconductor devices and a manufacturing method thereof concerning embodiments of the invention will be described with reference to the accompanying drawings.

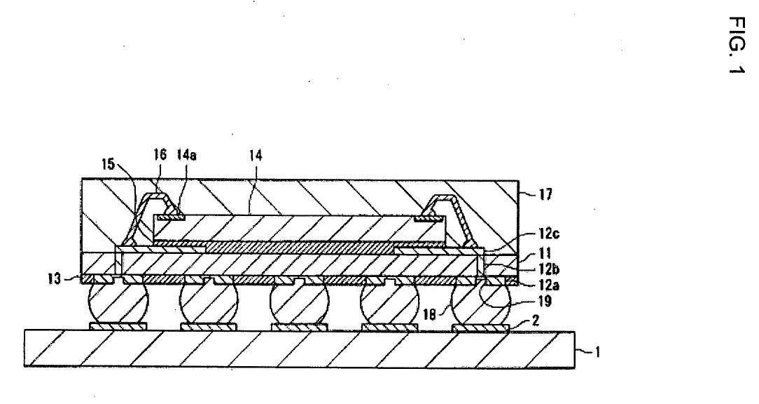

FIG. 1 is a sectional view showing a schematic configuration of a semiconductor device concerning an embodiment of the invention.

In FIG. 1, while an electric conduction pattern 12c is formed in the surface of a carrier substrate 11, a land 12a is formed in the back face of the carrier substrate 11. Here, a half slit 19 is formed in the bonding face of the land 12a.

Moreover, an internal wiring 12b is formed in the carrier substrate 11, and the electric conduction pattern 12c is coupled to the land 12a via the internal wiring 12b. Moreover, a solder resist layer 13 covering the periphery of the land 12a is formed on the carrier substrate 11. Then, a semiconductor chip 14 is face-up mounted on the carrier substrate 11 via an adhesive layer 15. Here, a pad electrode 14a is prepared in the semiconductor chip 14, and the pad electrode 14a is coupled to the electric conduction pattern 12c via a bonding wire 16. Moreover, the semiconductor chip 14 mounted on the carrier substrate 11 is sealed with a sealing resin 17. In addition, in sealing the semiconductor chip 14 with the sealing resin 17, molding with the use of a thermosetting resin, such as an epoxy resin can be used.

Moreover, on the land 12a prepared in the back face of the carrier substrate 11, a protruding electrode 18 for mounting the carrier substrate 11 on a motherboard 1 is prepared. Then, the carrier substrate 11 is mounted on the motherboard 1 by bonding the protruding electrode 18 to a land 2 prepared on the motherboard 1.

In addition, as the carrier substrate 11, for example, a double-sided substrate, a multi-layer interconnection substrate, a build-up substrate, a tape substrate, a film substrate or the like can be used, and as the quality of material of the carrier substrate 11, for example, a polyimide resin, a glass epoxy resin, BT resin, a composite of aramid and epoxy, ceramics or the like can be used. Moreover, as the base material of the electric conduction pattern 12c, and the lands 2 and 12a, for example, Cu can be used. Moreover, as the protruding electrode 18, for example, Au bump, Cu bump and Ni bump covered with solder material or the like can be used, other than a solder ball or a lead-free ball. Then, as the bonding wire 16, for example, Au wire, Al wire or the like can be used. Moreover, as the adhesive layer 15, for example, Ag paste or the like can be used. As the lead-free ball, an alloy of Sn—Ag—Cu, and an alloy of Sn—Ag—Cu—Bi may be used.

Moreover, other than the method for face-up mounting the semiconductor chip 14 on the carrier substrate 11, the semiconductor chip 14 may be flip-chip mounted on the carrier substrate 11. For example, in flip-chip mounting the semiconductor chip 14 on the carrier substrate 11, a crimp bonding such as ACF (Anisotropic Conductive Film), NCF (Nonconductive Film) bonding, ACP (Anisotropic Conductive Paste) bonding, NCF (Nonconductive Paste) bonding or the like may be used, or metal bonding such as solder bonding, alloy bonding or the like may be also used.

Then, in bonding the protruding electrode 18 to the land 12a, it is possible to bond the protruding electrode 18 directly to the base material of the land 12a. Here, by using Cu as the base material of the land 12a, it is possible to secure the strength in the peeling direction as compared with the case where plating such as Ni/Au is applied to the land 12a, and thus the impact resistance can be improved.

Moreover, while enabling the bonding area of between the protruding electrode 18 and land 12a to be increased by forming the half slit 19 in the bonding face of the land 12a, it is possible to cause the protruding electrode 18 to bite into the land 12a, and thus the lateral move of the protruding electrode 18 to be bonded to the land 12a can be suppressed. For this reason, even when the protruding electrode 18 is bonded directly to the base material of the land 12a, it is possible to suppress the deterioration of shearing strength, and thus the impact resistance can be improved while enabling the temperature cycle resistance and the ball shear strength to be secured.

In addition, when a solder ball or a lead-free ball is bonded to the land 12a whose base material is Cu, an organic film such as CuOSP may be formed on the land 12a. Moreover, in bonding the protruding electrode 18 to the land 2 prepared on the motherboard 1, the protruding electrode 18 may be bonded directly to the base material of the land 2.

Furthermore, in the above-described embodiment, as to the land 2 prepared on the mother board 1, a method for configuring the bonding face of the land 2 as to be flat has been described, however, also as to the land 2 prepared on the mother board 1, the half slit 19 may be formed in the bonding face of the land 2.

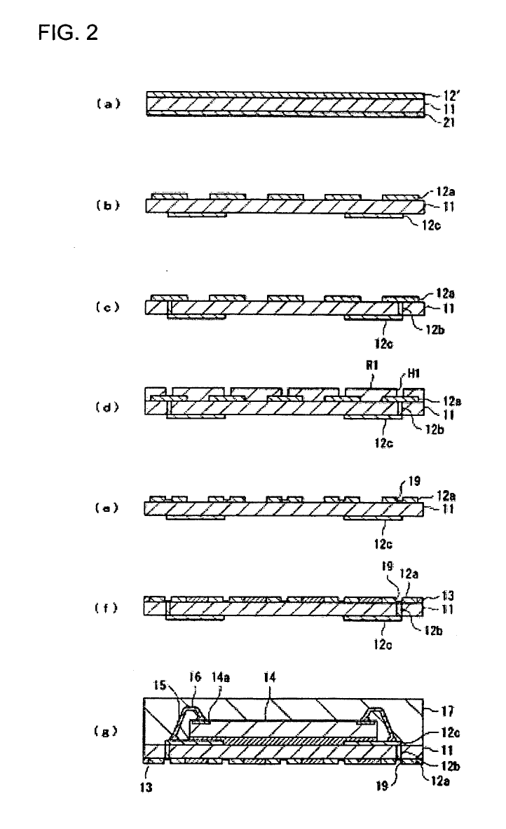

FIG. 2 is a sectional view showing a method for manufacturing the semiconductor device concerning the embodiment of the invention.

In FIG. 2(a), copper foils 12 and 12′ are stuck to both sides of the carrier substrate 11, respectively. Then, as shown in FIG. 2(b), by patterning the copper foils 12 and 12′, respectively, an electric conduction pattern 12c is formed on the carrier substrate 11, and lands 12a and 12a′ are formed in the back face of the carrier substrate 11.

In addition, in forming the electric conduction pattern 12c on the carrier substrate 11, a first photoresist corresponding to the shape of the electric conduction pattern 12c is formed on the copper foil 12 using a photolithography technique. Then, the electric conduction pattern 12c can be formed on the carrier substrate 11 by etching the copper foil 12 using the first photoresist as a mask. Moreover, in forming the land 12a and 12a′ in the back face of the carrier substrate 11, a second photoresist corresponding to the shape of the land 12a, 12a′ is formed on the copper foil 12′ using a photolithography technique. Then, the land 12a, 12a′ can be formed in the back face of the carrier substrate 11 by etching the copper foil 12′ using the second photoresist as a mask.

In this case, on the electric conduction pattern 12c, for example, a plated layer composed of a multi-layered structure of Ni/Au may be formed. In addition, the thickness of the land 12a may be set to, for example, approximately 10 through 30 μm, and the diameter of the land 12a may be set to, for example, approximately 300 through 400 μm.

Next, as shown in FIG. 2(c), an opening that penetrates the carrier substrate 11 therethrough is formed, and by burying a conductive material in the opening, an internal wiring 12b is formed in the carrier substrate 11. In addition, as the conductive material buried in the opening, for example, Cu paste or the like can be used.

Next, as shown in FIG. 2(d), a resist pattern R1 for exposing a part of the bonding face of the land 12a is formed in the back face of the carrier substrate 11 using a photolithography technique. Then, by carrying out a half etching of the land 12a using the resist pattern R1 as a mask, as shown in FIG. 2(e), a half slit 19 is formed in the bonding face of the land 12a. In addition, it is preferable that the depth of the half slit 19 be set to a half of the thickness of the land 12a or less. Moreover, it is preferable that the width of the half slit 19 be set in the range of approximately 10 through 50 μm. Moreover, the shape of the half slit 19 can be made in a cross shape, a lattice shape, or a concentric circle shape or the like. Then, after the half slit 19 is formed in the land 12a, the resist pattern R1 will be removed from the carrier substrate 11.

Next, as shown in FIG. 2(f), a solder resist layer 13 covering the periphery of the land 12a is formed on the carrier substrate 11. In addition, in forming the solder resist layer 13 on the carrier substrate 11, an insulating resin can be applied on the carrier substrate 1 via a mask configured as to cover the upper portion of the land 12a.

Next, as shown in FIG. 2(g), the semiconductor chip 14 is mounted on the carrier substrate 11 via the adhesive layer 15. Then, after coupling the pad electrode 14a to the electric conduction pattern 12c via the bonding wire 16, the semiconductor chip 14 is sealed with the sealing resin 17. Then, as shown in FIG. 1, the carrier substrate 11 is mounted on the motherboard 1 by bonding the protruding electrode 18 to the lands 2 and 12a.

In addition, although in the above-described embodiment, a method for forming the half slit 19 in the land 12a has been described, a penetrating slit in place of the half slit 19 may be prepared in the land 12a. Alternately, a coarse face, a recess or a cut may be prepared in the land 12a.

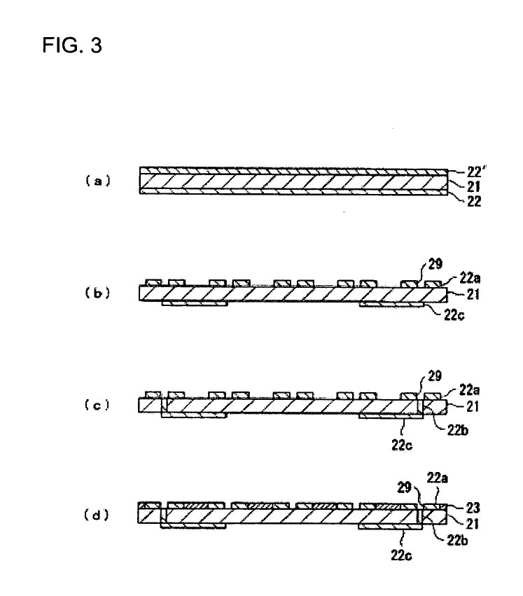

FIG. 3 is a sectional view showing a method for manufacturing a circuit substrate concerning a second embodiment of the invention.

In FIG. 3(a), copper foils 22 and 22′ are stuck to both sides of the carrier substrate 21, respectively. Then, as shown in FIG. 3(b), by patterning the copper foils 22 and 22′, respectively, an electric conduction pattern 22c is formed on the carrier substrate 21, and a land 22a, in which a penetrating slit 29 is prepared therein, is formed in the back face of the carrier substrate 21. In addition, it is preferable to set the width of the penetrating slit 29 to be equal to the thickness of the 22a or more.

Next, as shown in FIG. 3(c), an opening that penetrates the carrier substrate 21 therethrough is formed, and by burying a conductive material in the opening, an internal wiring 22b is formed in the carrier substrate 21. Next, as shown in FIG. 3(d), a solder resist layer 23 covering the periphery of the land 22a is formed on the carrier substrate 21.

Accordingly, at the time of forming the land 22a, it is possible to form the penetrating slit 29 in the land 22a simultaneously, and it is possible to cause the protruding electrode to bite into the land 22a. For this reason, the strength in the peeling direction can be secured without involving the increase of the process, and the deterioration of shearing strength can be suppressed. In addition, a cut in place of the penetrating slit 29 may be formed in the periphery of the land 22a.

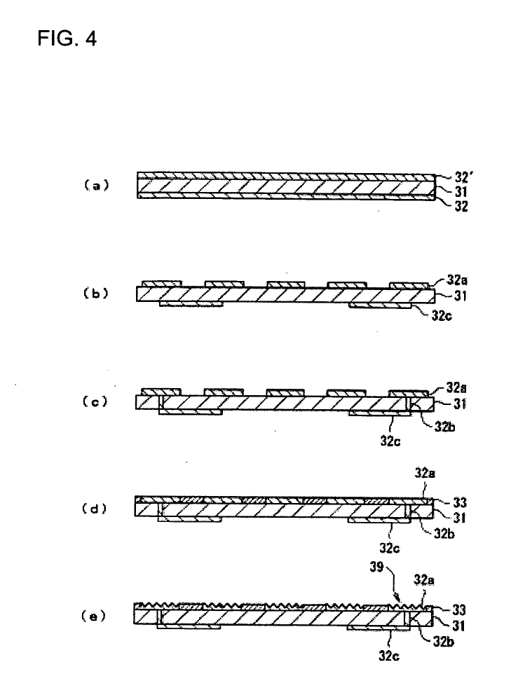

FIG. 4 is a sectional view showing a method for manufacturing a circuit substrate concerning a fourth embodiment of the invention.

In FIG. 4(a), copper foils 32 and 32′ are stuck to both sides of a carrier substrate 31, respectively. Then, as shown in FIG. 4(b), by patterning the copper foils 32 and 32′, respectively, an electric conduction pattern 32c is formed on the carrier substrate 31, while forming a land 32a in the back face of the carrier substrate 31.

Next, as shown in FIG. 4(c), an opening that penetrates the carrier substrate 31 therethrough is formed, and by burying a conductive material in the opening, an internal wiring 32b is formed in the carrier substrate 31. Next, as shown in FIG. 4(d), a solder resist layer 33 covering the periphery of the land 32a is formed on the carrier substrate 31.

Next, as shown in FIG. 4(e), by carrying out a surface treatment or a surface processing of the land 32a, a coarse face 39, the surface roughness of which is 20 through 100 μm, is formed in the surface of the land 32a. Here, as to the method for surface-treating the land 32a, for example, a stamping jig in which irregularities are formed in the surface thereof may be pressed onto the land 32a, or an aqueous solution containing abrasive compounds, such as glass beads, or air may be sprayed to the surface of the land 32a.

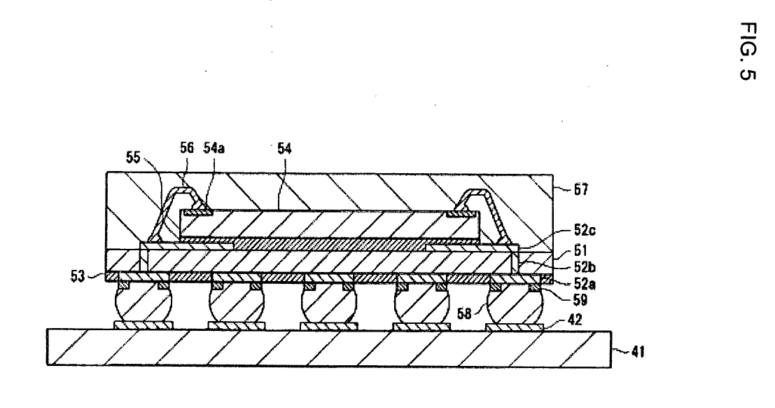

FIG. 5 is a sectional view showing a schematic configuration of a semiconductor device concerning a fifth embodiment of the invention.

In FIG. 5, while an electric conduction pattern 52c is formed in the surface of a carrier substrate 51, a land 52a is formed in the back face of the carrier substrate 51. Here, a plated layer 59 is formed in a part of the bonding face of the land 52a. In addition, as a plated layer 19, for example, a monolayer structure of Pd, a monolayer structure of Au, a monolayer structure of Sn, a multi-layered structure of Ni/Au, a multi-layered structure of Pd/Ni, or a multi-layered structure of Pd/Ni/Au may be used.

Moreover, an internal wiring 52b is formed in the carrier substrate 51, and the electric conduction pattern 52c is coupled to the land 52a via the internal wiring 52b. Moreover, a solder resist layer 53 covering the periphery of the land 52a is formed on the carrier substrate 51. Then, a semiconductor chip 54 is face-up mounted on the carrier substrate 51 via an adhesive layer 55. Here, a pad electrode 54a is prepared in the semiconductor chip 54, and the pad electrode 54a is coupled to the electric conduction pattern 52c via a bonding wire 56. Moreover, the semiconductor chip 54 mounted on the carrier substrate 51 is sealed with a sealing resin 57.

Moreover, on the land 52a prepared in the back face of the carrier substrate 51, a protruding electrode 58 for mounting the carrier substrate 51 on a motherboard 41 is prepared. Then, by bonding the protruding electrode 58 to the land 42 prepared on the motherboard 41, the carrier substrate 51 is mounted on the motherboard 41.

Then, after bonding the protruding electrode 58 directly to the base material of the land 52a by bonding the protruding electrode 58 to the land 52a, the protruding electrode 58 can be bonded also to the plated layer 59.

Here, by using Cu as the base material of the land 52a, it is possible to secure the strength in the peeling direction as compared with the case where plated layer such as Ni/Au is applied across the land 52a, and thus the impact resistance can be improved. Moreover, by forming the plated layer 59 in a part of the land 52a, the shearing strength can be improved as compared with the case where there is no plated layer 59. For this reason, it is possible to secure the strength in the peeling direction while suppressing the deterioration of shearing strength, and thus the temperature cycle resistance and the ball shear strength can be secured, and the impact resistance can be improved.

Moreover, in bonding the protruding electrode 58 to the land 42 prepared on the motherboard 41, the protruding electrode 58 may be bonded directly to the base material of the land 42. Alternatively, also as to the land 42 prepared on the motherboard 41, a plated layer may be prepared in a part of the bonding face of the land 42.

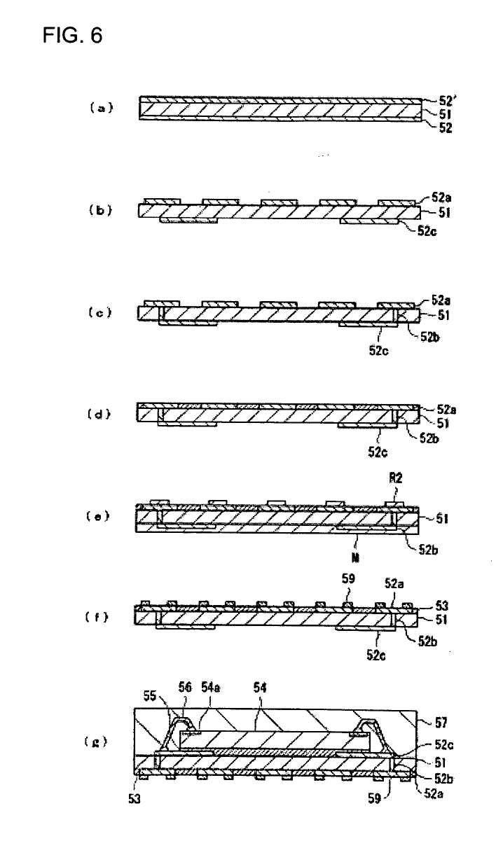

FIG. 6 is a sectional view showing a method for manufacturing the semiconductor device of FIG. 5.

In FIG. 6(a), copper foils 52 and 52′ are stuck to both sides of the carrier substrate 51, respectively. Then, as shown in FIG. 6(b), by patterning the copper foils 52 and 52′, respectively, an electric conduction pattern 52c is formed on the carrier substrate 51, and a land 52a is formed in the back face of the carrier substrate 51.

Next, as shown in FIG. 6(c), an opening that penetrates the carrier substrate 51 therethrough is formed, and by burying a conductive material in the opening, an internal wiring 52b is formed in the carrier substrate 51. Then, as shown in FIG. 6(d), a solder resist layer 53 covering the periphery of the land 52a is formed on the carrier substrate 51.

Next, as shown in FIG. 6(e), a masking tape M covering the electric conduction pattern 52c is stuck on the carrier substrate 51. Moreover, by using a photolithography technique, a resist pattern R2 covering a part of the bonding face of the land 52a is formed in the back face of the carrier substrate 51. Then, by carrying out a plating treatment to the carrier substrate 51 in which the resist pattern R2 is formed, a plated layer 59 is formed selectively in a part of the bonding face of the land 52a as shown in FIG. 6(f). In addition, in forming the plated layer in the electric conduction pattern 52c, a plating treatment of the carrier substrate 51 may be carried out without sticking the masking tape M on the carrier substrate 51. Then, after the plated layer 59 is formed selectively in a part of the bonding face of the land 52a, the resist pattern R2 and masking tape M will be removed from the carrier substrate 51.

Next, as shown in FIG. 6(g), the semiconductor chip 54 is mounted on the carrier substrate 51 via the adhesive layer 55. Then, after coupling the pad electrode 54a to the electric conduction pattern 52c via the bonding wire 56, the semiconductor chip 54 is sealed with the sealing resin 57. Then, as shown in FIG. 5, the carrier substrate 51 is mounted on the motherboard 41 by bonding the protruding electrode 58 to the lands 42 and 52a.

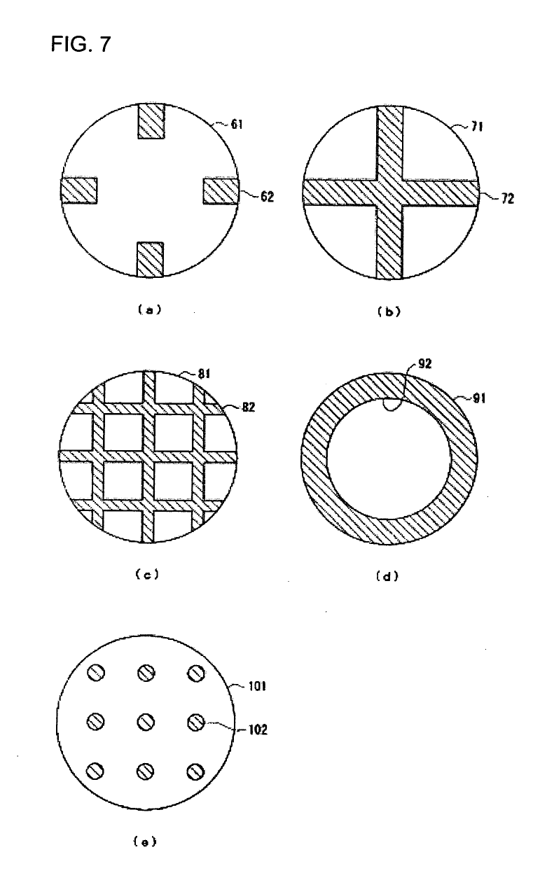

FIG. 7 is a plane view showing the configuration examples of the bonding face of the land concerning the embodiment of the invention.

As shown in FIG. 7(a), a plated layer 62 may be formed on the bonding face in the periphery of a land 61. Accordingly, it is possible to form the plated layer 62 in a part of the bonding face of the land 61, and thus after bonding the protruding electrode to the base material of the land 61, the protruding electrode can be bonded also to the plated layer 62, while enabling the protruding electrode to bite into the plated layer 62. For this reason, it is possible to secure the strength in the peeling direction in the bonding portion in between the protruding electrode and the base material of the land 61, while the shearing strength can be secured in the bonding portion in between the protruding electrode and the plated layer 62, and thus the impact resistance can be improved while suppressing the deterioration of shearing strength.

In addition, as shown in FIG. 7(b), a plated layer 72 may be formed in a cross shape on the bonding face of a land 71. Moreover, a plated layer 82 may be formed in a lattice shape on the bonding face of a land 81. Moreover, a plated layer 92 may be formed in the shape of a concentric circle on the bonding face of a land 91. Moreover, a plated layer 102 may be formed in the shape of scattered dots on the bonding face of a land 101.

Note that in the embodiments of FIG. 7, the shapes of the plated layer formed on the bonding face of the land have been described, however, as to the recess, slit, or cut formed on the land, the same shapes as those of FIG. 7 may be also used.

What is claimed is:

1. A semiconductor device, comprising:
a carrier substrate in which a semiconductor chip is mounted; and
a land formed in the carrier substrate and arranged in a surface different from a mounting face of the semiconductor chip,
wherein a recess is formed in a bonding face of the land.

2. A semiconductor device, comprising:
a carrier substrate in which a semiconductor chip is mounted; and
a land formed in the carrier substrate and arranged in a surface different from a mounting face of the semiconductor chip,
wherein a slit is formed in a bonding face of the land.

3. A semiconductor device, comprising:
a carrier substrate in which a semiconductor chip is mounted;
a land formed in the carrier substrate and arranged in a surface different from a mounting face of the semiconductor chip; and
a plated layer formed in a part of a bonding face of the land.

4. The semiconductor device according to claim 3, wherein the plated layer is a monolayer structure of Pd, a monolayer structure of Au, a monolayer structure of Sn, a multi-layered structure of Ni/Au, a multi-layered structure of Pd/Ni, or a multi-layered structure of Pd/Ni/Au.

5. The semiconductor device according to claim 1, further comprising:
a protruding electrode bonded to the land; and
a motherboard in which the carrier substrate is mounted via the protruding electrode.

6. The semiconductor device according to claim 5, wherein the base material of the land is Cu, and the protruding electrode is a solder ball or a lead-free ball.
